(19) United States
(12) Patent Application Publication
(10) Pub. No.: US 2025/0374378 A1
(43) Pub. Date: Dec. 4, 2025

(54) Thermal test vehicle

(71) Applicant: Purple Cloud Development Pte. Ltd., Singapore (SG)

(72) Inventors: Hsiang-Chieh Tseng, Singapore (SG); Sy-Chi KUO, Singapore (SG)

(21) Appl. No.: 18/679,696

(22) Filed: May 31, 2024

(30) Foreign Application Priority Data
May 10, 2023 (TW) 112204548

(51) Int. Cl. H05B 3/26; G06F 1/20; H05B 1/02

(52) U.S. Cl. CPC H05B 3/265; H05B 1/023; G06F 1/20; H05B 2203/01

(57) ABSTRACT

A thermal test vehicle including a base plate, first cold plate, heat resistor, second cold plate, plurality of insulation layers, and one or more sensors is provided. The first cold plate is positioned within the base plate and the heat resistor is positioned over the first cold plate and the second cold plate is positioned over the heat resistor. The plurality of insulation layers includes a second insulator plate. The second insulator plate is positioned between the heat resistor and the second cold plate. The second insulator plate transfers at least an other portion of heat flux from the heat resistor to the second cold plate. At least a portion of heat flux from the heat resistor is transferred from a heat source to the first cold plate. The one or more sensors is positioned within at least one of the second cold plate and first cold plate.

### RELATED APPLICATIONS

This US application claims the benefit of priority to Taiwan application no. 112204548, filed on May 10, 2023, of which is incorporated herein by reference in its entirety.

### TECHNICAL FIELD

The present disclosure is related to processor cooling testing and analysis in general and more particularly but not limited to thermal test vehicles.

### BACKGROUND OF THE INVENTION

For computer systems such as servers, processing units generate heat that is removed using cooling systems, such as air and/or liquid cooling systems. The design of cooling systems is often based on estimates formed from properties of the processing units. Often, assumptions made during the design process are incorrect and may lead to less efficient cooling systems. Insufficient cooling of the processing units may adversely affect the performance of the computer system, and speeds of the processing units may be reduced, resulting in failure.

Thermal test vehicles (TTVs) mimic power dissipation of different processor units and may be used in the development and investigation of cooling systems for computer systems. The TTVs may be a non-functional processor package. At least one heat resistor of the TTV may be used to simulate the power dissipation of the processing units. A variety of heat flux dissipation patterns may be applied to the heat resistor during simulation. A temperature of the heat resistor may be monitored by at least one temperature sensor.

However, as operating temperatures of processing units increase, accurate testing and analysis of the cooling systems have become challenging. For TTVs, with higher operating temperatures, a temperature difference between the heat resistor and what is monitored by the temperature sensor is increased. The increased temperature difference increases standard deviation and decreases accuracy of the temperature readings; thus, causing measurement errors. Additionally, with higher operating temperatures, heat resistance of the heat resistor may be deficient. Thus, an insulator film of the heat resistor deteriorates faster, leading to faulty data readings, burn-through, short-circuiting, and/or damage of the TTV. Moreover, with higher operating temperatures, operating lifespan of the heat resistor is decreased, thus increasing costs for maintenance, repair and replacement.

### SUMMARY OF THE INVENTION

The present disclosure provides a thermal test vehicle including a base plate, a first cold plate, a heat resistor, a second cold plate, a plurality of insulation layers, and one or more sensors. The first cold plate is positioned within the base plate, the heat resistor is positioned over the first cold plate, the second cold plate is positioned over the heat resistor, and a second insulator plate of the plurality of insulation layers is positioned between the heat resistor and the second insulator plate. At least one of the one or more sensors is positioned within the second cold plate. A transfer of at least an other portion of heat flux from the heat resistor to the second cold plate via the second insulator plate hinders short-circuiting of the conductive heating element and increases operating lifespan of the thermal test vehicle.

In at least one embodiment, a thermal test vehicle includes a base plate, a first cold plate, a heat resistor, a second cold plate, a plurality of insulation layers, and one or more sensors. The first cold plate is positioned within the base plate. The heat resistor is positioned over the first cold plate, opposite the base plate. The first cold plate receives at least a portion of a heat flux generated by the heat resistor. The second cold plate is positioned over the heat resistor. The second cold plate receives at least an other portion of the heat flux generated by the heat resistor. The plurality of insulation layers includes a second insulator plat. The second insulator plate is positioned between the heat resistor and the second cold plate. The second insulator plate transfers the at least an other portion of the heat flux from the heat resistor to the second cold plate. At least a portion of the heat flux is transferred from a heat source to the first cold plate. The one or more sensors is configured to respectively measure a temperature of the second cold plate and the first cold plate.

In at least one embodiment, the plurality of insulation layers further includes a first insulator plate positioned between the heat resistor and the first cold plate. The first insulator plate further transfers the at least a portion of the heat flux from the heat resistor to the first cold plate.

In at least one embodiment, the plurality of insulation layers further includes a first insulation material layer, a second insulation material layer, a third insulation material layer, and a fourth insulation material layer. The first insulation material layer is positioned between the heat resistor and the first insulator plate. The second insulation material layer is positioned between the heat resistor and the second insulator plate. The third insulation material layer is positioned between the second insulator plate and the second cold plate. The fourth insulation material layer is positioned between the first insulator plate and the first cold plate. The second insulation material layer and the third insulation material layer, both, respectively further transfer the at least an other portion of the heat flux from the heat resistor to the second cold plate. The first insulation material layer and the fourth insulation material layer, both, further respectively transfer the at least a portion of the heat flux from the heat resistor to the first cold plate.

In at least one embodiment, the base plate further includes a pair of plates disposed on the base plate. Each of the pair of plates is longitudinal and adjacent to two respective opposing sides of the base plate. The first cold plate, the heat resistor, the second cold plate, the plurality of insulation layers, and the one or more sensors are positioned between the pair of plates. In at least one embodiment, each of the pair of plates opposite the base plate have equal top surface planes, and a top plate surface plane of the second cold plate opposite the second insulator plate is between the second insulator plate and the equal top surface planes.

In at least one embodiment, the heat resistor includes an insulator film, a conductive heating element, and one or more cables. The conductive heating element is disposed on the insulator film and the insulator film is positioned over the first cold plate opposite the conductive heating element. The one or more cables is electrically coupled to the conductive heating element and the heat resistor generates heat flux via the one or more cables and the conductive heating element.

In at least one embodiment, the first insulator plate and the second insulator plate, both, further respectively comprise a thermal conductivity and a heat resistance greater than a thermal conductivity and a heat resistance of the insulator film. In at least one embodiment, the first insulator plate and the second insulator plate, both, further respectively comprise an aluminum nitride ceramic plate.

In at least one embodiment, the first cold plate includes a first longitudinal groove, the second cold plate includes a second longitudinal groove, and the one or more sensors include a first sensor and a second sensor. The first longitudinal groove is disposed within a first top surface of the first cold plate opposite the base plate. The second longitudinal groove is disposed within a second top surface of the second cold plate opposite the heat resistor. The first sensor is positioned within the first longitudinal groove, and the second sensor is positioned within the second longitudinal groove.

In at least one embodiment, the base plate includes a first plate side, a second plate side, and a plate recess. The first plate side is opposite the second plate side and the plate recess disposed within the first plate side. The first cold plate is positioned within the base plate via the plate recess. In at least one embodiment, the base plate further includes a cable slot. The cable slot is disposed through the base plate. The cable slot is longitudinal to one side of the plate recess. At least a portion of the cable slot is between the pair of plates. The first sensor, the second sensor, and the one or more cables are positioned through the cable slot.

In at least one embodiment, the thermal test vehicle further includes a mount plate. The mount plate includes a plurality of fasteners. The base plate is positioned over the mount plate and mounted to the mount plate via the plurality of fasteners.

### BRIEF DESCRIPTION OF DRAWINGS

Unless specified otherwise, the accompanying drawings illustrate aspects of the innovative subject matter described herein. Referring to the drawings, wherein like reference numerals indicate similar parts throughout the several views, several examples of thermal test vehicles incorporating aspects of the presently disclosed principles are illustrated by way of example, and not by way of limitation.

FIG. 1A is a perspective view of a thermal test vehicle according to one embodiment of the present disclosure.

FIG. 1B is an exploded view of the thermal test vehicle of FIG. 1A according to one embodiment of the present disclosure.

FIG. 2 is a partial cross-sectional view of another thermal test vehicle according to one embodiment of the present disclosure.

FIG. 3 is a partial cross-sectional view of yet another thermal test vehicle according to one embodiment of the present disclosure.

### DETAILED DESCRIPTION

The following describes various principles related to systems for processor cooling testing and analysis by way of reference to specific examples of thermal test vehicles, including specific arrangements and examples of cold plates and heat resistors embodying innovative concepts. More particularly, but not exclusively, such innovative principles are described in relation to selected examples of at least two of a plurality of insulation layers sandwiching a heat resistor transferring heat flux to a first cold plate and a second cold plate, and well-known functions or constructions are not described in detail for purposes of succinctness and clarity. Nonetheless, one or more of the disclosed principles can be incorporated in various other embodiments of different insulation layers transferring heat flux of the heat resistor to cold plates to achieve any of a variety of desired outcomes, characteristics, and/or performance criteria.

Thus, electronic modules and retention joints having attributes that are different from those specific examples discussed herein can embody one or more of the innovative principles, and can be used in applications not described herein in detail. Accordingly, embodiments of insulation layers, heat resistors, and cold plates not described herein in detail also fall within the scope of this disclosure, as will be appreciated by those of ordinary skill in the relevant art following a review of this disclosure.

Example embodiments as disclosed herein are directed to processor cooling testing and analysis using thermal test vehicles (TTVs). The processor can include central processing units (CPUs), graphics processing units (GPUs), neural network processing units (NPUs), tensor processing units (TPUs) etc. The TTVs can be a non-functional processor package. In addition to being used in the development and investigation of cooling systems, the TTVs may also be used to investigate the thermal characteristics and reliability of processor packages, investigate the impact of hot spots and power density variations on the processor packages based on different simulation scenarios, and investigate the thermal characteristics and reliability of thermal interface materials (TIMs).

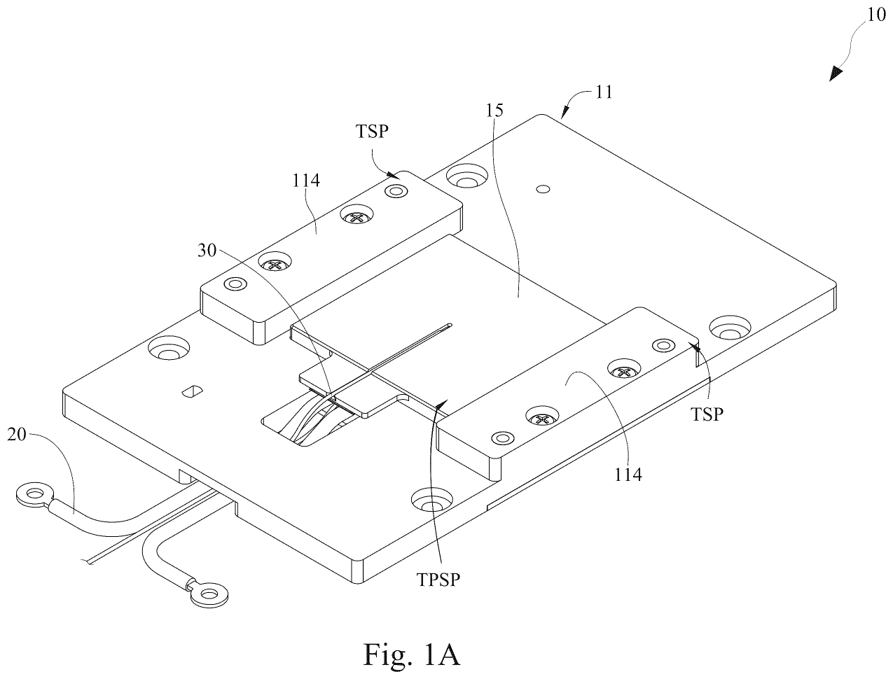

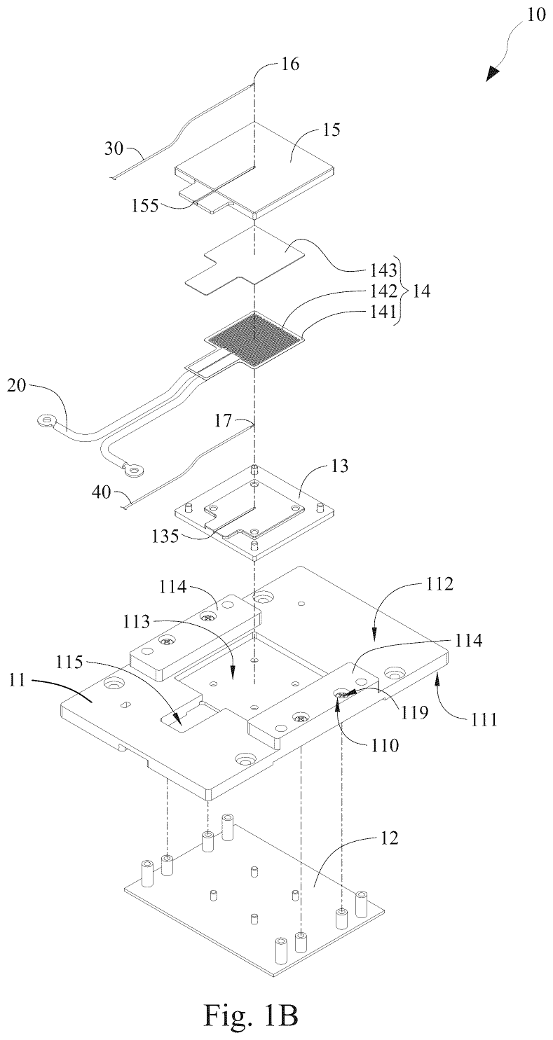

FIGS. 1A and 1B include at least one embodiment of a thermal test vehicle 10. The thermal test vehicle 10 includes a base plate 11, a first cold plate 13, a heat resistor 141, 142, a second cold plate 15, a plurality of insulation layers 143, and one or more sensors 16, 17. The first cold plate 13 is positioned within the base plate 11. The heat resistor 141, 142 is positioned over the first cold plate 13, opposite the base plate 11. The first cold plate 13 receives at least a portion of a heat flux generated by the heat resistor 141, 142. The second cold plate 15 is positioned over the heat resistor 141, 142. The second cold plate 15 receives at least an other portion of the heat flux generated by the heat resistor 141, 142. The plurality of insulation layers 143 include a second insulator plate 143. The second insulator plate 143 is positioned between the heat resistor 141, 142 and the second cold plate 15. The second insulator plate 143 transfers the at least an other portion of the heat flux from the heat resistor 141, 142 to the second cold plate 15. At least a portion of the heat flux is transferred from a heat source to the first cold plate 13. The one or more sensors 16, 17 is configured to respectively measure a temperature of the second cold plate 15 and the first cold plate 13. In at least one embodiment, the one or more sensors 16, 17 can include a temperature sensor. A resistance temperature detector (RTD) is a type of temperature sensor where resistance changes with changes in temperature.

In at least one embodiment, the base plate 11 further includes a pair of plates 114 disposed on the base plate 11. Each of the pair of plates 114 is longitudinal and adjacent to two respective opposing sides of the base plate 11. The first cold plate 13, the heat resistor 141, 142, the second cold plate 15, the plurality of insulation layers 143, and the one or more sensors 16, 17 are positioned between the pair of plates 114. In at least one embodiment, each of the pair of plates 114 opposite the base plate 11 have equal top surface planes TSP, and a top plate surface plane TPSP of the second cold plate 15 opposite the second insulator plate 143 is between the second insulator plate 143 and the equal top surface planes TSP.

In at least one embodiment, the heat resistor 141, 142 includes an insulator film 141, a conductive heating element 142, and one or more cables 20. The conductive heating element 142 is disposed on the insulator film 141 and the insulator film 141 is positioned over the first cold plate 13 opposite the conductive heating element 142. The one or more cables 20 is electrically coupled to the conductive heating element 142 and the heat resistor 141, 142 generates heat flux via the one or more cables 20 and the conductive heating element 142. In at least one embodiment, the insulator film 141 can be a polyimide (PI) film or PI electrothermal film. In at least one embodiment, the insulator film 141 can include thermal conductivity of 0.1-0.2 W/(m·K), inclusive.

In at least one embodiment, the first cold plate 13 includes a first longitudinal groove 135, the second cold plate 15 includes a second longitudinal groove 155, and the one or more sensors 16, 17 include a first sensor 17 and a second sensor 16. The first longitudinal groove 135 is disposed within a first top surface of the first cold plate 13 opposite the base plate 11. The second longitudinal groove 155 is disposed within a second top surface of the second cold plate 15 opposite the heat resistor 141, 142. The first sensor 17 is positioned within the first longitudinal groove 135, and the second sensor 16 is positioned within the second longitudinal groove 155. In at least one embodiment, the first sensor 17 is electrically coupled to one of the one or more cables 40 and the second sensor 16 is electrically coupled to an other of the one or more cables 30.

In at least one embodiment, the base plate 11 includes a first plate side 112, a second plate side 111, and a plate recess 113. The first plate side 112 is opposite the second plate side 111 and the plate recess 113 disposed within the first plate side 112. The first cold plate 13 is positioned within the base plate 11 via the plate recess 113. In at least one embodiment, the base plate 11 further includes a cable slot 115. The cable slot 115 is disposed through the base plate 11. The cable slot 115 is longitudinal to one side of the plate recess 113. At least a portion of the cable slot 115 is between the pair of plates 114. The first sensor 17, the second sensor 16, and the one or more cables 40, 20, 30 are positioned through the cable slot 115.

In at least one embodiment, the thermal test vehicle 10 further includes a mount plate 12. The mount plate 12 includes a plurality of fasteners 119. The base plate 11 is positioned over the mount plate 12 and mounted to the mount plate 12 via the plurality of fasteners 119. In at least one embodiment, the plurality of fasteners 119 can be screws mounting the base plate 11 to the mount plate 12 via a plurality of holes 110 respectively through each of the pair of plates 114.

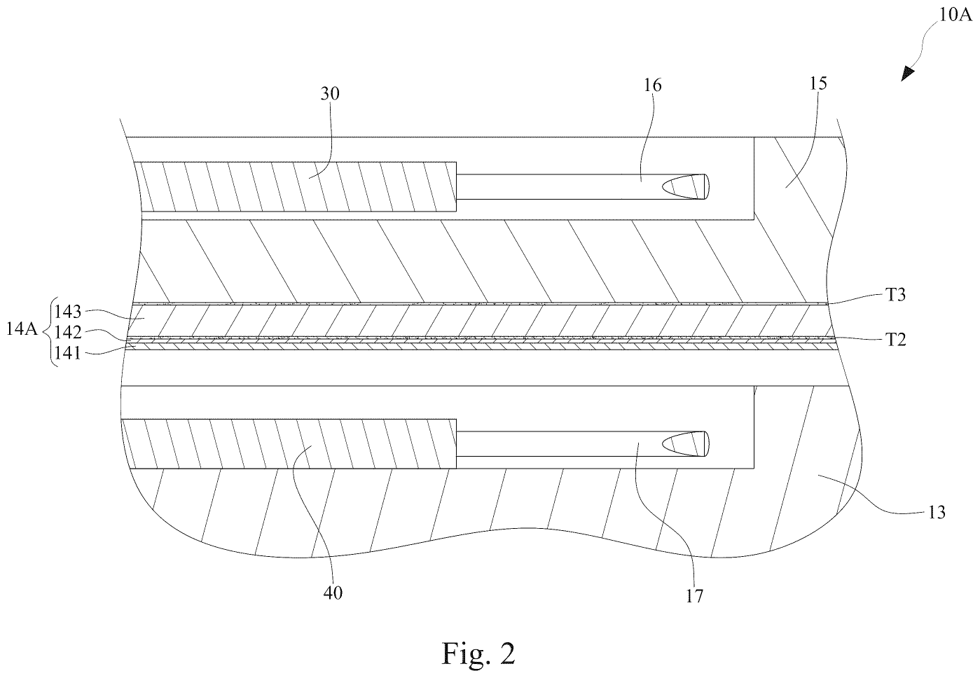

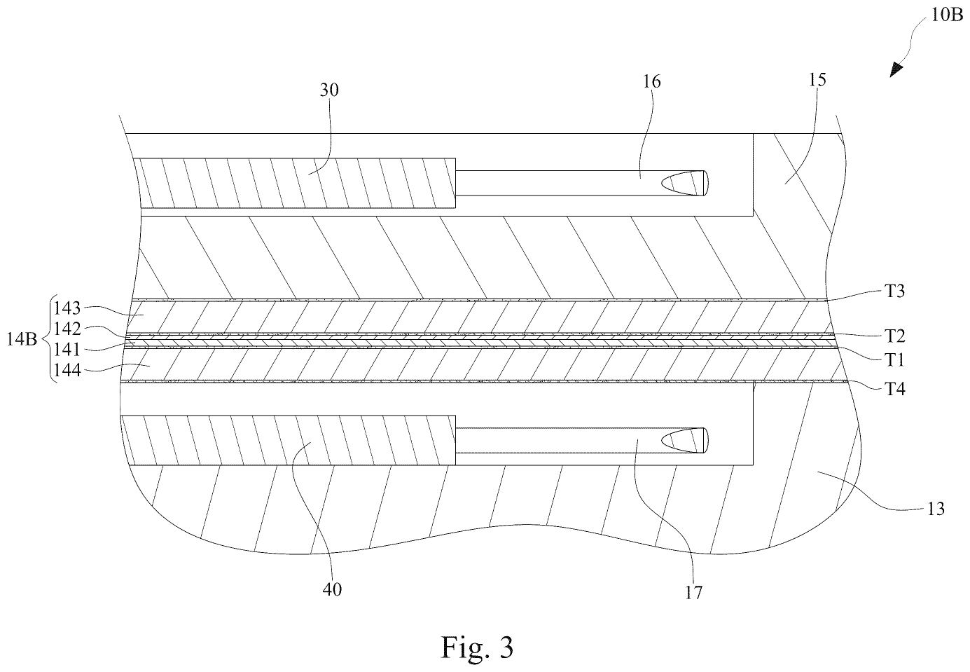

FIG. 2 includes at least one embodiment of another thermal test vehicle 10A. The another thermal test vehicle 10A may be similar in some respects to the thermal test vehicle 10 of FIGS. 1A and 1B, and therefore may be best understood with reference thereto where like numerals designate like components not described again in detail. FIG. 3 includes at least one embodiment of yet another thermal test vehicle 10B. The yet another thermal test vehicle 10B may be similar in some respects to the thermal test vehicle 10 of FIGS. 1A and 1B, and therefore may be best understood with reference thereto where like numerals designate like components not described again in detail.

In at least one embodiment, the plurality of insulation layers 143 of the thermal test vehicle 10B further includes a first insulator plate 144 positioned between the heat resistor 141, 142 and the first cold plate 13. The first insulator plate 144 further transfers the at least a portion of the heat flux from the heat resistor 141, 142 to the first cold plate 13. In at least one embodiment, the plurality of insulation layers 143 of the thermal test vehicle 10 further includes a first insulation material layer T1, a second insulation material layer T2, a third insulation material layer T3, and a fourth insulation material layer T4. The first insulation material layer T1 is positioned between the heat resistor 141, 142 and the first insulator plate 144. The second insulation material layer T2 is positioned between the heat resistor 141, 142 and the second insulator plate 143. The third insulation material layer T3 is positioned between the second insulator plate 143 and the second cold plate 15. The fourth insulation material layer T4 is positioned between the first insulator plate 144 and the first cold plate 13. The second insulation material layer T2 and the third insulation material layer T3, both, respectively further transfer the at least an other portion of the heat flux from the heat resistor 141, 142 to the second cold plate 15. The first insulation material layer T1 and the fourth insulation material layer T4, both, respectively further transfer the at least a portion of the heat flux between the heat source and the first cold plate 13.

In at least one embodiment, the heat resistor 14A (141, 142) further comprises the second insulation material layer T2 and the second insulator plate 143 of the plurality of insulation layers T2, 143, integrally formed therewith. The second insulation material layer T2 is between the conductive heating element 142 and the third insulation material layer T3. In at least one embodiment, the heat resistor 14B (141, 142) yet further comprises the first insulation material layer T1 and the first insulator plate 144 of the plurality of insulation layers T2, 143, T1, 144 integrally formed therewith; in addition to the second insulation material layer T2 and the second insulator plate 143. The first insulation material layer T1 is between the insulator film 141 and the first insulator plate 144.

In at least one embodiment, the first insulation material layer T1, the second insulation material layer T2, the third insulation material layer T3, and the fourth insulation material layer T4 can respectively include a thermal interface material (TIM). In at least one embodiment, the first insulation material layer T1, the second insulation material layer T2, the third insulation material layer T3, and the fourth insulation material layer T4 can respectively include a thermally conductive paste. In at least one embodiment, the thermally conductive paste can have a high conductivity coefficient. In at least one embodiment, the first insulation material layer T1 couples the heat resistor 141, 142 to the first insulator plate 144, the second insulation material layer T2 couples the heat resistor 141, 142 to the second insulator plate 143, the third insulation material layer T3 couples the second insulator plate 143 to the second cold plate 15, and the fourth insulation material layer T4 couples the first insulator plate 144 to the first cold plate 13.

In at least one embodiment, the first insulator plate 144 and the second insulator plate 143 can respectively have thermal conductivity of 180 W/(m·K) and can respectively have heat resistance of over 1,000° C. In at least one embodiment, the first insulator plate 144 and the second insulator plate 143 can respectively include an aluminum nitride (AlN) ceramic plate. In at least one embodiment, the first cold plate 13 and the second cold plate 15 can respectively include a metal plate having high thermal conductivity. In at least one embodiment, the first cold plate 13 and the second cold plate 15 can respectively include a copper cold plate.

In at least one embodiment of a thermal test vehicle 10A, the thermal test vehicle 10A includes a base plate 11, a first cold plate 13, a heat resistor 141, 142, a second cold plate 15, a plurality of insulation layers T2, 143, T3, and one or more sensors 16, 17. The first cold plate 13 is positioned within the base plate 11. The heat resistor 141, 142 is positioned over the first cold plate 13, opposite the base plate 11. The first cold plate 13 receives at least a portion of a heat flux generated by the heat resistor 141, 142. The second cold plate 15 is positioned over the heat resistor 141, 142. The second cold plate 15 receives at least an other portion of the heat flux generated by the heat resistor 141, 142. The plurality of insulation layers T2, 143, T3 include a second insulation material layer T2, a second insulator plate 143, and a third insulation material layer T3. The second insulator plate 143 is positioned between the heat resistor 141, 142 and the second cold plate 15 and the second insulation material layer T2 is between the heat resistor 141, 142 and the second insulator plate 143 and the third insulation material layer T3 is between the second insulator plate 143 and the second cold plate 15. The second insulator plate 143 transfers the at least an other portion of the heat flux from the heat resistor 141, 142 to the second cold plate 15. At least a portion of the heat flux is transferred from a heat source to the first cold plate 13. The one or more sensors 16/30, 17/40 is configured to respectively measure a temperature of the second cold plate 15 and the first cold plate 13. The one or more sensors 16/30, 17/40 comprise a second sensor 16/30 positioned within a second longitudinal groove 155 of the second cold plate 15 and a first sensor 17/40 positioned within a first longitudinal groove 135 of the first cold plate 13. As an example, a power supply provides a continuous load of 1,200 Watts to the heat resistor 141, 142 of a thermal test vehicle. Under the continuous load the heat resistor 141, 142 records a temperature of 116.32° C. and the second cold plate 15, via the second sensor 16/30, records a temperature of 115.41° C. An operating lifespan of the heat resistor 141, 142 under the continuous load is over 1,000 hours. When the second insulator plate 143 is replaced by a top insulator film, under a continuous load of 1,200 Watts, the heat resistor 141, 142 records a temperature of 161.95° C. and the second cold plate 15, via the second sensor 16/30, records a temperature of 91.35° C. An operating lifespan of the heat resistor 141, 142 under the continuous load is 480 hours. The second insulator plate 143 decreases the temperature difference between the second cold plate 15 and the heat resistor 141, 142 from 70.6° C. to 0.91° C., and increases the operating lifespan of the heat resistor 141, 142 by over 2×.

The thermal test vehicles 10, 10A, 10B of the present disclosure can accurately test and analyze cooling systems having high operating temperature processing units. The transfer of the at least an other portion of the heat flux from the heat resistor 141, 142 to the second cold plate 15 via the second insulator plate 143 hinders short-circuiting of the conductive heating element 142. The second insulator plate 143 has greater heat resistance and higher thermal conductivity when compared to a top insulator film covering the conductive heating element 142, and can replace the top insulator film positioned between the heat resistor 141, 142 and the second cold plate 15. The top insulator film is prone to faster deterioration and greater damage due to high heat flux of the heat resistor 141, 142 when compared to the first insulator plate 144 as the temperature difference between the second cold plate 15 and the heat resistor 141, 142 is decreased from 70.6° C. to 0.91° C. Thus, accuracy of temperature readings via the second sensor 16/30 is improved due to decreased standard deviation of the decreased temperature difference and measurement errors are decreased. Also, deterioration of the top insulator film leading to faulty data readings, short-circuiting of the conductive heating element 142, and burn through of the top insulator film is eliminated or mitigated. Moreover, operating lifespan of the heat resistor 141, 142 is increased, thus decreasing costs for maintenance, repair and replacement.

Furthermore, the transfer of the at least a portion of the heat flux between the heat source and the first cold plate 13 via the first insulator plate 144 further hinders short-circuiting of the conductive heating element 142. The first insulator plate 144 has greater heat resistance and higher thermal conductivity than the insulator film 141 and enhances the insulator film 141. Thus, accuracy of temperature readings via the first sensor 17/40 is further improved due to decreased standard deviation of temperature differences and measurement errors are decreased. Also, deterioration of the insulator film 141 leading to faulty data readings, short-circuiting of the conductive heating element 142, and burn through of the insulator film 141 is mitigated. Moreover, operating lifespan of the heat resistor 141, 142 is further increased, thus further decreasing costs for maintenance, repair and replacement.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some number. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces.

1. A thermal test vehicle, comprising:
a base plate,
a first cold plate positioned within the base plate,
a heat resistor positioned over the first cold plate, opposite the base plate, the first cold plate receiving at least a portion of a heat flux generated by the heat resistor,
a second cold plate positioned over the heat resistor, the second cold plate receiving at least an other portion of the heat flux generated by the heat resistor,
a plurality of insulation layers, the plurality of insulation layers including a second insulator plate, the second insulator plate positioned between the heat resistor and the second cold plate, the second insulator plate transferring the at least an other portion of the heat flux from the heat resistor to the second cold plate, at least a portion of the heat flux is transferred from a heat source to the first cold plate, and
one or more sensors configured to respectively measure a temperature of the second cold plate and the first cold plate.

2. The thermal test vehicle of claim 1, wherein the plurality of insulation layers further comprises a first insulator plate positioned between the heat resistor and the first cold plate, the first insulator plate further transferring the at least a portion of the heat flux from the heat resistor to the first cold plate.

3. The thermal test vehicle of claim 2, wherein the plurality of insulation layers further comprises a first insulation material layer, a second insulation material layer, a third insulation material layer, and a fourth insulation material layer, the first insulation material layer positioned between the heat resistor and the first insulator plate, the second insulation material layer positioned between the heat resistor and the second insulator plate, the third insulation material layer positioned between the second insulator plate and the second cold plate, and the fourth insulation material layer positioned between the first insulator plate and the first cold plate, the second insulation material layer and the third insulation material layer, both, respectively further transferring the at least an other portion of the heat flux from the heat resistor to the second cold plate, the first insulation material layer and the fourth insulation material layer, both, respectively further transferring the at least a portion of the heat flux from the heat resistor to the first cold plate.

4. The thermal test vehicle of claim 2, wherein the base plate further comprises a pair of plates, the pair of plates disposed on the base plate, each of the pair of plates longitudinal and adjacent to two respective opposing sides of the base plate, the first cold plate, the heat resistor, the second cold plate, the plurality of insulation layers, and the one or more sensors positioned between the pair of plates.

5. The thermal test vehicle of claim 4, wherein each of the pair of plates opposite the base plate have equal top surface planes, and a top plate surface plane of the second cold plate opposite the second insulator plate is between the second insulator plate and the equal top surface planes.

6. The thermal test vehicle of claim 2, wherein the first insulator plate and the second insulator plate, both, further respectively comprise an aluminum nitride ceramic plate.

7. The thermal test vehicle of claim 4, wherein the heat resistor comprises an insulator film, a conductive heating element, and one or more cables, the conductive heating element disposed on the insulator film, the insulator film positioned over the first cold plate opposite the conductive heating element, the one or more cables electrically coupled to the conductive heating element, the heat resistor generating heat flux via the one or more cables and the conductive heating element.

8. The thermal test vehicle of claim 7, wherein the first insulator plate and the second insulator plate, both, further respectively comprise a thermal conductivity and a heat resistance greater than a thermal conductivity and a heat resistance of the insulator film.

9. The thermal test vehicle of claim 7, wherein the first cold plate comprises a first longitudinal groove, the second cold plate comprises a second longitudinal groove, and the one or more sensors comprise a first sensor and a second sensor, the first longitudinal groove disposed within a first top surface of the first cold plate opposite the base plate, the second longitudinal groove disposed within a second top surface of the second cold plate opposite the heat resistor, the first sensor positioned within the first longitudinal groove, and the second sensor positioned within the second longitudinal groove.

10. The thermal test vehicle of claim 9, wherein the base plate comprises a first plate side, a second plate side, and a plate recess, the first plate side opposite the second plate side, the plate recess disposed within the first plate side, the first cold plate positioned within the base plate via the plate recess.

11. The thermal test vehicle of claim 10, wherein the base plate further comprises a cable slot, the cable slot disposed through the base plate, the cable slot longitudinal to one side of the plate recess, at least a portion of the cable slot between the pair of plates, the first sensor, the second sensor, and the one or more cables positioned through the cable slot.

12. The thermal test vehicle of claim 1, further comprising a mount plate, the mount plate including a plurality of fasteners, the base plate positioned over the mount plate, the base plate mounted to the mount plate via the plurality of fasteners.
